(19) United States
(12) Patent Application Publication
(10) Pub. No.: US 2019/0103821 A1
(43) Pub. Date: Apr. 4, 2019

(54) Displacement Connectors of High Bending Stiffness and Piezoelectric Actuators Made of Such

(71) Applicant: MICROFINE MATERIALS TECHNOLOGIES PTE LTD, Singapore (SG)

(72) Inventors: Leong Chew LIM, Singapore (SG); Yu HUANG, Singapore (SG); Yuexue XIA, Singapore (SG); Dian-Hui LIN, Singapore (SG)

(21) Appl. No.: 16/091,789

(22) PCT Filed: Apr. 7, 2016
(86) PCT No.: PCT/SG2016/050173

§ 371 Date: Oct. 5, 2018

(51) Int. Cl. H02N 2/04; B06B 1/06

(52) U.S. Cl. CPC H02N 2/043; H01L 41/1875; B06B 1/0618

(57) ABSTRACT

Disclose displacement connectors of high bending stiffness, high-performance piezoelectric actuators and derivative devices made of such. The connector has circumferentially alternating recess housings which, when fitted with the intended piezoelectric active elements makes displacement actuators, approximately double (2×), triple (3×) or quadruple (4×) the displacement of individual active elements without adversely jeopardizing their regenerative forces. The connector may take any overall cross-section and length to suit intended applications. Connector recesses can be configured to house piezoelectric elements of a wide variety of cross-sections and dimensions, including longitudinal mode stacks, transverse mode bars and/or tubes, single crystal blocks of suitable cut and dimensions and their bonded assemblages.

### TECHNICAL FIELD

The present invention relates to displacement connectors of high bending stiffness and, in particular, to high-performance piezoelectric actuators.

### BACKGROUND

Compact, high-authority and high-fidelity piezoelectric actuators, i.e. those of relatively high displacements (≥60 μm) and blocking forces (≥50N) and with minimum hysteresis, are needed in many technological sectors including industrial, aerospace, defense, medical and scientific. Reference is made to “The Shock and Vibration Digest”, vol. 33 (2001), pp. 269-280, Titled: “Piezoelectric actuation: state of the art”, by Niezrecki, C. et al.).

Direct push-pull piezoelectric actuators include longitudinal (d₃₃) stacked and transverse (d₃₁) tube actuators. They are of large blocking forces but low displacements, typically being about >100 N and <40 μm. To attain displacement >40 μm, stacks consisting of hundreds of layers and measuring more than 100 mm in height are commercially available. Schematics of direct push-pull piezoelectric actuators according to prior art are provided in FIGS. 1A-1C. FIG. 1A illustrates a transverse (d₃₁ and d₃₂) bar 101, FIG. 1B illustrates a transverse (d₃₁) tube 102, and FIG. 1C illustrates a longitudinal (d₃₃) stack 103. As shown in FIGS. 1A-1C, short arrows indicate the electrical poling direction used in the fabrication of respective active materials and large dual-head arrows indicate the activating (i.e., intended displacement) direction.

The starting material can be any individual direct push-pull piezoelectric rectangular bar, rod or tube of either longitudinal (d₃₃) or transverse (d₃₁ or d₃₂) mode (FIGS. 1A and 1B) including their assemblages, such as d₃₃ stacks (FIG. 1C), bonded transverse-mode bars of solid or hollow cross-sections, including but not limited to bonded assemblages of piezoelectric single crystals of triangular, square and other polygonal-pipe cross-sections as disclosed in International Patent Application No: PCT/SG2012/000493, Titled: “Cost-effective single crystal multi-stake actuator and method of manufacture”, by Xia, Y. X et al. They are hereafter collectively referred to as the “active elements”.

Preferably, the active elements should be ones of high piezoelectric strain coefficients and hence displacement strokes. Examples of such constructs include stacked bars, rods or hollow cylinders of longitudinal (d₃₃) mode of piezo-ceramics and single crystals, and individual or assemblage of transverse (d₃₂ and d₃₁) bars of piezo-single crystals.

In direct push-pull application, for a given applied electric field or voltage, the displacement of an active element is proportional to its dimension in the active direction, while the blocking force is proportional to its cross-sectional (or load bearing) area. Simple actuators made of these direct push-pull elements typically have high regenerative forces but limited displacements, being typically >100 N and <40 μm.

Various displacement enhancement mechanisms have been devised to increase the displacement of these direct push-pull active elements, including lever-arm (FIGS. 2A-2B), flextensional (FIGS. 3A-3C), and meander-line and/or telescopic (FIGS. 4A-4B) approaches.

U.S. Pat. No. 4,570,095, Titled: “Mechanical amplification mechanism combined with piezoelectric elements” issued to Uchikawa, and U.S. Pat. No. 4,783,610, Titled: “Piezoelectric actuator” issued to Asano, disclose lever-arm actuators. Such lever-arm actuators utilize the lever-arm mechanism to increase the displacement of direct push-pull actuators although the force output of the device is decreased as a result. In such a design, the fulcrum typically consists of a thin flexible member while the arm is much thicker and hence much more rigid. In addition to being displacement actuators, they are popularly used as grippers in robots. Schematics of various lever-arm actuators 111 and 112 according to prior art are provided in FIGS. 2A-2B respectively.

Flextensional actuators are disclosed in U.S. Pat. No. 3,277,433, Titled: “Flexural-extensional electromechanical transducer” issued to Toulis, and “Applied Acoustics”, vol. 3 (1970), pp. 117-126, Titled: “The flextensional concept: A new approach to the design of underwater acoustic transducers” by Royster, L. H. Flextensional actuators comprise a group of actuators in which the motion generated by the push-pull actuator is converted to a much larger displacement in the transverse direction by means of an elastic flextensional member, the latter typically being made of metal. They include the oval (in U.S. Pat. No. 5,742,561, Titled: “Transversely driven piston transducer” issued to Johnson), moonie (in U.S. Pat. No. 5,276,657, Titled: “Metal-electroactive ceramic composite actuators”, issued to Newnham), cymbal (in U.S. Pat. No. 5,729,077, Titled: “Metal-electroactive ceramic composite transducer”, issued to Newnham) and bow (Integrated Ferroelectrics, vol. 82 (2006), pp. 25-43, Titled: “Piezo-bow high displacement and high blocking force actuator” by Joshi, M. et al., 2006) actuators. Moonie and cymbal actuators consist of a piezoelectric disk sandwiched by two end caps. Radial displacement of the disk flexes the end caps, producing much enhanced displacement in the axial direction. Schematics of various flextensional actuators 121, 122 and 123 for enhancing the displacement of push-pull actuators according to prior art are provided in FIGS. 3A-3C respectively. The lead wires connecting to the active materials are not shown for clarity of illustration.

Telescopic, in U.S. Pat. No. 4,510,412, Titled: “Piezoelectric displacing devices” issued to Suda, and meander-liner, in Transactions of the IEEE Ultrasonics, Ferroelectrics and Frequency Control, vol. 38 (1991), pp. 454-460, Titled: “High displacement piezoelectric actuator utilizing meander-line geometry Part 1: Experimental characterization” by Robbins, W. P. et al., architectures have also been used to increase the displacement of push-pull actuators. Such actuators, however, are brittle when the entire actuator is molded as a single-piece piezo-ceramic. Schematics of telescopic and meander-line actuators 131 and 132 according to prior art are provided in FIGS. 4A-4B respectively. The lead wires connecting to the active materials are not shown for clarity of illustration.

However, all the displacement enhancement mechanisms of prior art suffer from high bending compliance, severely compromising the performance of the resultant actuators.

Due to large bending compliance of the mechanical connectors used for displacement enhancement, both the displacement and blocking forces of devices made of the above-described displacement enhancement mechanisms are adversely affected as a result.

Stacked actuators and hence active elements of solid triangular cross-section however, remain unavailable to-date due possibly to their weak sharp corners and higher cost of fabrication. Similarly, transverse mode active elements of triangular-pipe cross-section also remain unavailable to date.

A need, therefore, exists for connector of High Bending Stiffness (HBS) that overcomes the above drawbacks.

### SUMMARY OF THE INVENTION

The following summary is provided to facilitate an understanding of some of the innovative features unique to the disclosed embodiment and is not intended to be a full description. A full appreciation of the various aspects of the embodiments disclosed herein can be gained by taking into consideration the entire specification, claims, drawings, and abstract as a whole.

It is, therefore, one aspect of the disclosed embodiments to provide for a connector of High Bending Stiffness (HBS) that has minimum or no bending displacement.

It is, therefore, another aspect of the disclosed embodiments to provide for HBS-connectors having alternating recess housings which are arranged circumferentially to enable the top and bottom-directed active elements to be fitted circumferentially.

It is, therefore, yet another aspect of the disclosed embodiments to provide for HBS-connectors having the cross-section of the recess housings as close as possible to that of the active elements to reduce the load span at their bases.

It is, therefore, another aspect of the disclosed embodiments to provide for HBS-connectors having the bases of the recesses firmly connected to the main body of the connector to eliminate possible cantilever effect.

It is, therefore, another aspect of the disclosed embodiments to provide for HBS-connectors having a thick outer ring or shell to further minimize its bending displacement during use.

It is, therefore, yet another aspect of the disclosed embodiments to provide for connectors of high bending stiffness, through the use of additional top and bottom stiffening plates where appropriate.

It is, therefore, yet another aspect of the disclosed embodiments to provide for a high bending stiffness (HBS) connectors and displacement multipliers having circumferentially alternating recess housings and a sufficiently thick outer ring or shell when needed which, when fitted with the intended piezoelectric active elements to make displacement actuators, approximately double (2×), triple (3×) or quadruple (4×) the displacement of individual active elements without adversely jeopardizing their regenerative forces.

It is, therefore, yet another aspect of the disclosed embodiments to provide for a connector that may take any overall cross-section and length to suit intended applications.

It is, therefore, yet another aspect of the disclosed embodiments to provide for a connector in which the recess housings can be suitably configured to house piezoelectric elements of a wide variety of cross-sections and dimensions, including longitudinal mode stacks, transverse mode bars and/or tubes, single crystal blocks of suitable cut and dimensions and their bonded assemblages.

It is, therefore, yet another aspect of the disclosed embodiments to provide for derivative devices such as high-performance displacement actuators and compact Langevin low-frequency underwater projectors, made of HBS, HBS-2×, HBS-3× and HBS-4× connectors.

It is, therefore, yet another aspect of the disclosed embodiments to provide for active elements of solid triangular or triangular-pipe cross-section of either longitudinal (d₃₃) mode or transverse (d₃₁ or d₃₂) mode.

Other aspects and advantages of the invention will become apparent from the following detailed description, taken in conjunction with the accompanying drawings, illustrating by way of example the principles of the invention.

### BRIEF DESCRIPTIONS OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the disclosure is not limited to specific methods and instrumentalities disclosed herein. Moreover, those in the art will understand that the drawings are not to scale. Wherever possible, like elements have been indicated by identical numbers.

FIG. 1A-1C show schematics of prior art direct push-pull piezoelectric actuators of various configurations of transverse (d₃₁ and d₃₂) bar, transverse (d₃₁) tube and longitudinal (d₃₃) stack respectively;

FIGS. 2A and 2B show schematics of various prior art lever-arm designs for enhancing the displacement of push-pull actuators;

FIGS. 3A-3C show schematics various prior art flextensional designs for enhancing the displacement of push-pull actuators;

FIGS. 4A and 4B show schematics of meander-line and telescopic designs for enhancing the displacement of push-pull actuators respectively;

FIGS. 5A and 5B show an example of cylindrical HBS-2× (element-to-element) connector of the present invention having six equally-spaced recess housings of circular cross-section, three per level or per set of either top-directing or bottom-directing recesses;

FIGS. 6A-6CC show examples of possible designs of HBS-2×-connector of the present invention, wherein, FIGS. 6A-6F show those with two active elements per level,

FIGS. 6G-6K those with three active elements per level, FIGS. 6L-6Q those with more than three active elements per level for elements of different cross-sections, while FIGS. 6R-6W show connectors of different overall cross-sections, and FIGS. 6X-6CC are example designs of 2×-HBS-connector in which the total number of alternating recess housings and hence the active elements are kept to the minimum;

FIGS. 7A and 7B show an example of the use of thin but high-stiffness load pads of appropriate dimensions which are bonded to the base of individual recess housings of a HBS-2×-connector of the present invention to further limit the deflection of the bases during use;

FIG. 8 shows an example of the use of specially-shaped thin but high-stiffness plates which are screwed or bonded rigidly onto the top and bottom faces of a HBS-2×-connector of the present invention to further limit the deflection of the connector;

FIGS. 9A and 9B show an example of a multi-part design of an HBS-2×-connector, in accordance with the present invention;

FIGS. 10A-10C show examples of suitable openings made in the main body of a HBS-2×-connector of the present invention for easy device fabrication purposes;

FIG. 11 shows various views of an example of a square HBS-2×-assemblage, in accordance with the present invention;

FIG. 12 shows an example of a two-level actuator made of a cylindrical HBS-2×-assemblage, in accordance with the present invention;

FIG. 13 shows an example of a ring HBS-2×-connector having six active elements of rectangular cross-section, three per level;

FIGS. 14A-14N show examples of possible designs of ring and pseudo-ring HBS-2×-connectors, in accordance with the present invention;

FIG. 15 shows an example of a ring HBS-2×-assemblage, in accordance with the present invention;

FIG. 16 shows an example of a two-level ring actuator made of a ring HBS-2×-assemblage, in accordance with the present invention;

FIG. 17 shows an example of a concentric ring HBS-2×-connector design, in accordance with the present invention;

FIG. 18 shows a modified design of the concentric ring HBS-2×-connector of FIG. 17 with shorter outer shell for ease of device fabrication;

FIG. 19 shows another design of improved bending stiffness of present invention in which the outer ring recess is replaced with segmented recesses of either rectangular or curved cross-sections for housing individual active elements of matching cross-section;

FIG. 20 shows an example of HBS-2×-assemblage of the present invention consisting of a HBS-2×-connector shown in FIG. 17;

FIG. 21 shows an example design of a cylindrical HBS-3×-connector in accordance with the present invention;

FIG. 22 shows another example design of cylindrical HBS-3×-connector of concentric ring configuration of FIG. 21;

FIG. 23 shows an example of a three-level actuator made from the HBS-3×-connector of FIG. 21;

FIG. 24 shows yet an example of a three-level actuator made from the HBS-3×-connector of FIG. 22;

FIG. 25 shows an example of a three-level actuator as in FIG. 24 but with additional top and/or bottom stiffening disks or plates for high blocking force application;

FIG. 26 shows yet another example of a HBS-3×-connector, in accordance with the present invention;

FIG. 27 shows an example design of a HBS-4×-connector, in accordance with the present invention;

FIG. 28 shows another example design of the HBS-4×-connector of the present invention but of polygonal overall cross-section instead;

FIG. 29 shows an example of a four-level actuator made from the HBS-4×-connector of FIG. 27;

FIG. 30 shows an example of a design of an HBS-4×-actuator suitable for high blocking force applications;

FIG. 31 shows an example of a design of an HBS-4×-connector and assemblage of the present invention, in which all the top- and bottom-directed cylindrical HBS-2×-assemblages are positioned circumferentially; and

FIG. 32 shows an example of derivative device made from an HBS-2×-connector, in accordance with the present invention.

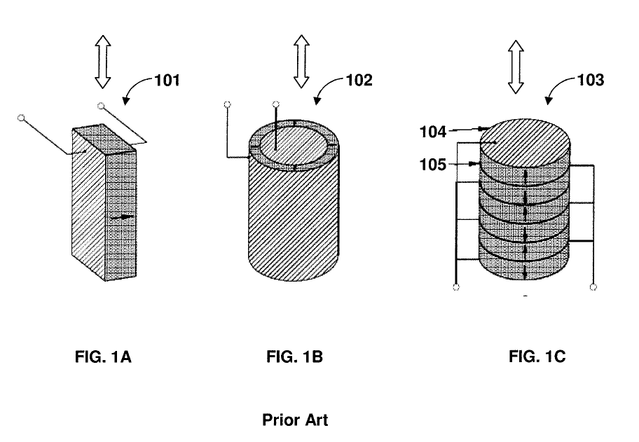

### DETAILED DESCRIPTION OF THE INVENTION

The particular values and configurations discussed in these non-limiting examples can be varied and are cited merely to illustrate at least one embodiment and are not intended to limit the scope thereof.

Three types of high bending stiffness (HBS) connectors-cum-displacement multipliers are disclosed:(i) HBS element-to-element (2×) connectors and associated HBS-2×-assemblage, (ii) HBS-element-to-assemblage (3×) connectors, and (iii) HBS assemblage-to-assemblage (4×) connectors. These devices, when fitted with piezoelectric active elements and accompanied inactive parts, are referred to as: (i) HBS-2×-actuators, (ii) HBS-3×-actuators and (iii) HBS-4×-actuators, respectively.

2×-High-Bending Stiffness (HBS) Connectors, Assemblages and Actuators

The HBS-2×-assemblage, or HBS-assemblage refers to a HBS-2×-connector fitted with appropriately wired active elements, but without any pedestal, base plate, or casing included, such as found in an actuator fabrication.

Typical materials and compounds for these active elements are lead zirconate titanate [PbZrO₃-PbTiO₃] piezo-ceramics and their compositionally modified derivatives, and/or high-piezoelectricity lead-based relaxor solid solution single crystals of suitable compositions and cuts, including lead zinc niobate-lead titanate [Pb(Zn_{1/3}Nb_{2/3})O₃—PbTiO₃], lead magnesium niobate-lead titanate [Pb(Mg_{1/3}Nb_{2/3})O₃—PbTiO₃], lead magnesium niobate-lead zirconate-lead tinanate [Pb(Mg_{1/3}Nb_{2/3})O₃-PbZrO₃—PbTiO₃], lead indium niobate-lead magnesium-niobate-lead titanate [Pb(In_{1/2}Nb_{1/2})O₃-Pb(Mg_{1/3}Nb_{2/3})O₃—PbTiO₃] solid solutions and their compositionally modified derivatives. In an exemplary embodiment, each piezoelectric active element comprises one of: (i) a longitudinal (d₃₃) mode active element, (ii) a transverse (d₃₁) mode active element, or (iii) a transverse (d₃₂) mode active element, each active element comprising either a single piece or multi-piece bonded assemblage of piezo-ceramics or piezo single crystals.

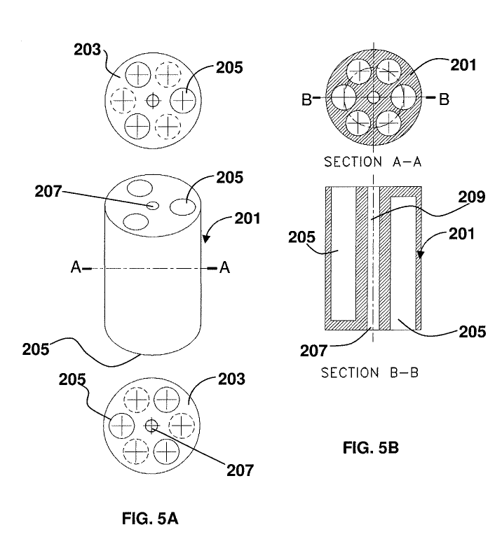

An exemplary embodiment of an HBS-2×-connector 201 is provided in FIG. 5A, comprising a component which has a substantially cylindrical overall shape with upper and lower bases 203. FIG. 5B shows section A-A and section B-B views of the HBS-2×-connector 201. The upper and lower bases 203 are unitary with the cylindrical portion of the HBS-2×-connector 201, that is, may be fabricated as a single unit for maximum rigidity and resistance to bending. The upper and lower bases 203 are also referred as first and second bases 203. The bases 203 may be in opposed parallel configuration to one another, as shown in the illustration, with the planes of the bases 203 substantially perpendicular to a longitudinal axis 209 of the HBS-2×-connector 201 shown in Section B-B. The HBS-2×-connector 201 contains specially-shaped and equally-spaced connector recesses 205 for housing a total of six longitudinal (d₃₃) or transverse (d₃₁ or d₃₂) mode push-pull piezoelectric active elements (not shown) and accordingly, providing an electromechanical transducer of novel and useful configuration.

It should be understood that more or fewer than six piezoelectric active elements or element stacks comprising: (i) a piezoelectric rectangular bar, a rod or a tube of either longitudinal (d₃₃) or transverse (d₃₁ or d₃₂) mode crystals,(ii) including their assemblages, such as d₃₃ stacks, bonded transverse-mode bars of solid or hollow cross-sections, (iii) including but not limited to bonded assemblages of piezoelectric single crystals of triangular cross-section, or square cross-section, or other polygonal-pipe cross-sections, can be used in any of the HBS-2×-assemblages described herein and claimed as the invention.

In the exemplary embodiment of FIG. 5A, three connector recesses 205 extend into the HBS-2×-connector 201 from each base 203. That is, the long dimensions of the connector recesses 205 are substantially parallel with the longitudinal axis 209 of the HBS-2×-connector 201. This configuration accommodates both top-directing and bottom-directing active elements, and is further present in the embodiments disclosed herein and illustrated in the figures described below. The configuration shown in FIG. 5A is for housing, or substantially enclosing, active elements of circular cross-section, but active elements of other cross sectional shapes can also be accommodated in connector recesses of different cross-sectional shapes, as shown in the various figures described below. For example the piezoelectric active elements comprise a cross sectional shape of a solid triangle, a hollow triangle, a solid square, a hollow square, a rectangle, a solid circle, a ring, or a pseudo-ring of a polygonal form. A central connector hole 207 passes through the HBS-2×-connector 201 and is used for the insertion of an optional stress rod (not shown) in making the actuator, or electromechanical transducer. In an exemplary embodiment, the longitudinal axis of the central connector hole 207 is coincident with the longitudinal axis 209.

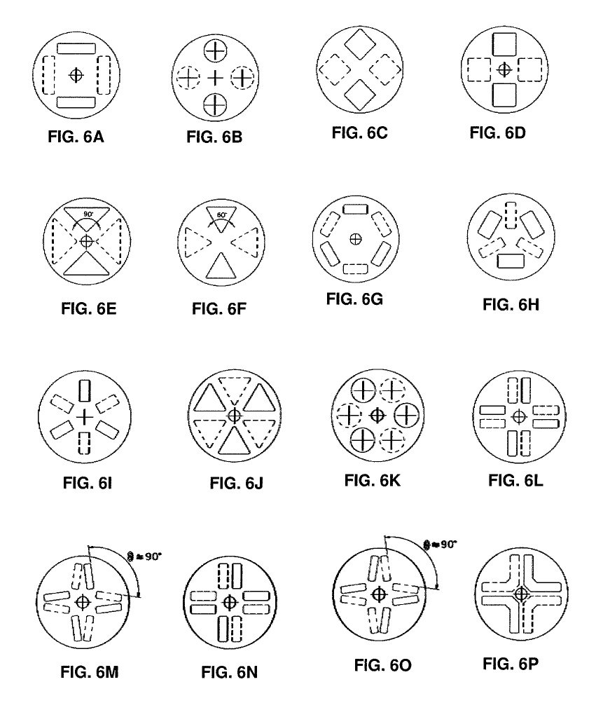

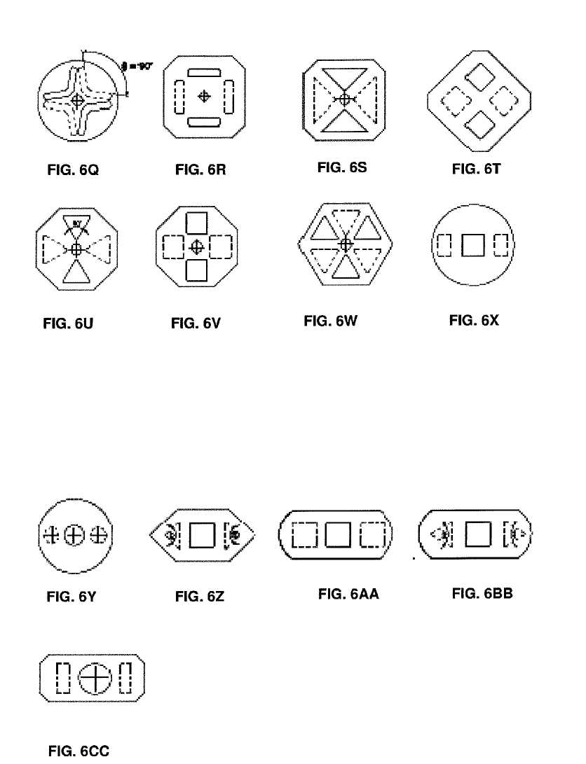

FIGS. 6A-6CC show schematic plan views of additional exemplary configurations of HBS-2×-connectors of the present invention, in which the solid lines represent the profiles of the connector recesses for the top set of active elements, while the hidden (dashed) lines represent connector recesses for the bottom set of active elements. FIGS. 6A-6F are related to designs with two active elements per level. FIGS. 6G-6K are related to designs with three elements per level. FIGS. 6L-6Q are related to designs with more than three elements per level. FIGS. 6R-6W represent connectors of different overall cross-sections.

For cost effectiveness purposes, the HBS-2×-connectors may be configured such that the number of alternating connector recesses and hence that of the active elements employed are kept to the minimum possible, provided that the resultant displacement device is stable during use, as can be seen in the design examples of HBS-2×-connectors shown in FIGS. 6X-6CC. Moreover, the elements and the connectors can be of any suitable cross-sections, and the number of elements per level may vary to suit a particular application. An optional central connector hole, shown in some configurations, provides for the insertion of a stress rod in making the actuator.

As can be appreciated by one skilled in the art, other similar examples of HBS-2×-connectors are also possible, where the HBS-2×-connectors include the following key features.

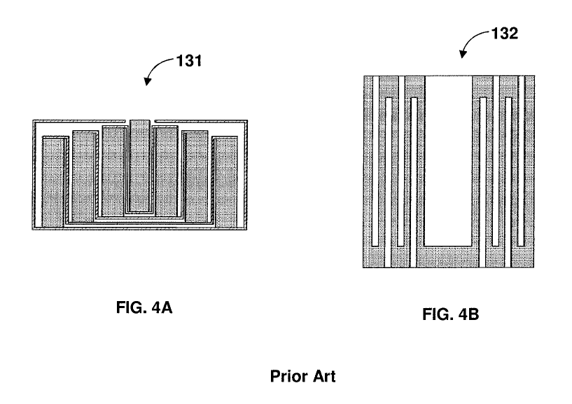

For the HBS-2×-connectors of the present invention, the alternative connector recesses for the top- and bottom-directed elements (i.e., the top and bottom sets of active elements) are arranged circumferentially as opposed to radially as in prior art (e.g., FIG. 4). And, to avoid large bending compliance exhibited by actuators of prior art, preferably, a one-piece connector design is adopted such that the cross-sections of the connector recesses are kept as close as possible to that of the active elements to minimize the load span. The bases form a unit with the cylindrical body of the connector along their circumferences to eliminate cantilever loading effects. The all-round support of the bases along their circumferences, with minimum load span and cantilever loading, are key features of the present invention which together account for the high rigidity of the connector and hence bending stiffness. As seen from FIG. 5B, and the other figures below, each connector recess extending from one base is disposed either: (i) between two connector recesses extending from the other base, or (ii) adjacent to at least one connector recess extending from the other base.

In addition to the all-round support along the circumference, the bases of the connector are of sufficient thicknesses and rigidity to limit deflection of the connector to an accepted value under full load.

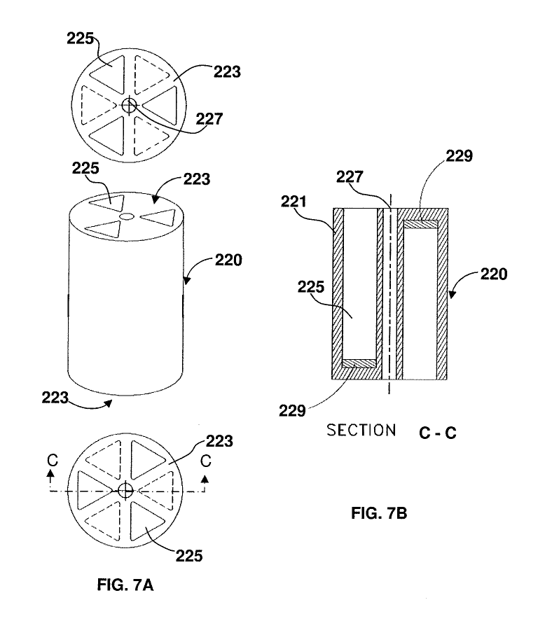

As a means to further reduce the deflection of the bases of the connectors, thin but high-stiffness load pads of cross-sections approximating that of a connector recess may be bonded onto the base inside a respective connector recess. An example of such reduction in deflection is shown in a modified connector 220 in FIG. 7A in which connector recesses 225 are meant to house active elements of triangular cross-section. As can be seen from the illustration, the connector 221 is similar to the connector 201 in FIG. 5A with the exception that the connector 221 includes the connector recesses 225 of triangular cross-sectional shape, rather than circular cross sectional shapes as found in the connector recesses 205. In the example provided, in FIG. 7A, three connector recesses 225 extend from each base 223. The modified connector 220 includes a central connector hole 227 for an optional stress rod (not shown). As shown in the cross sectional view C-C of FIG. 7B, a stiffening pad 229 may be bonded, or otherwise attached, to the bottom of one or more of the interior surfaces of the connector recesses 225.

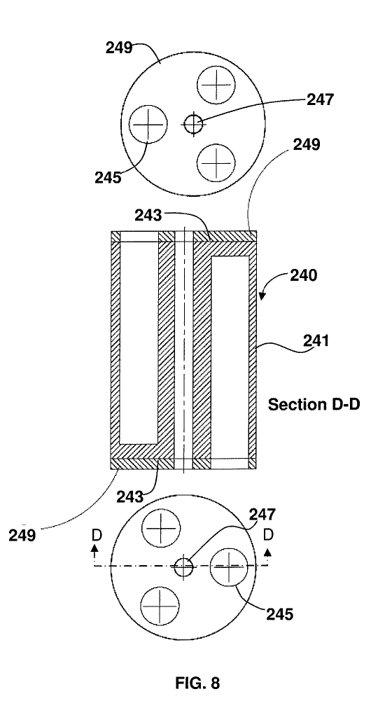

Alternatively, suitably shaped top and bottom stiffening plates 249 may be used as top and bottom connector bases. The top and bottom stiffening plates 249 can be mechanically fastened and/or bonded to the connector 241. Moreover, the top and bottom stiffening plates 249 can be used instead of, or in addition to, the stiffening pads 229 as in FIG. 7B, as in a modified connector 240 shown in FIG. 8. Top and bottom stiffening plates 249 may be screwed and/or bonded rigidly onto the bases 243 of a connector 241 in the modified connector 240. The stiffening plates 249 preferably have suitable openings 245, 247 to enable active elements or stress rod (not shown) to protrude and function as intended.

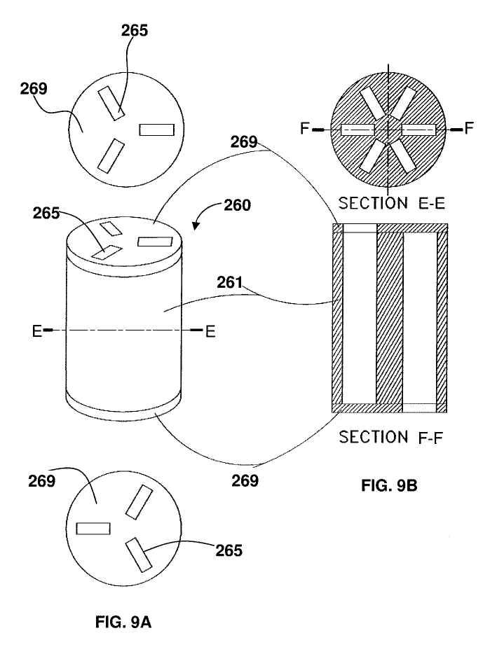

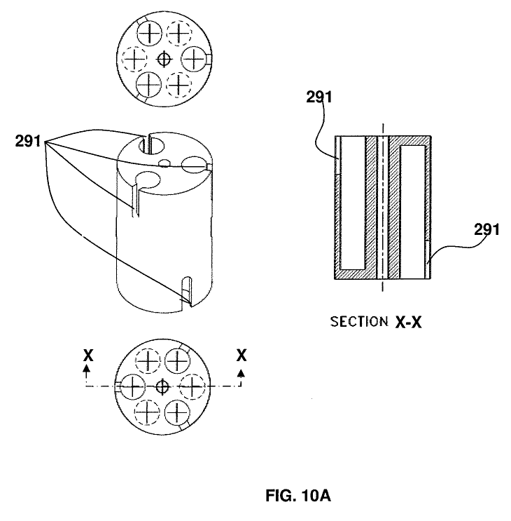

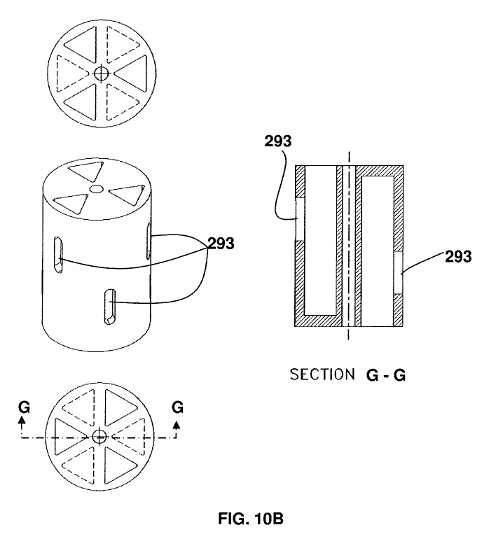

Alternatively, a multi-part design of a modified HBS-2×-connector 260 may be adopted, as shown in FIGS. 9A-9B, in which connector recesses 265 in a connector 261 are configured to house active elements of rectangular cross-section (not shown). In such a design, the rectangular through-holes, also referred as the connector recesses 265 in the connector 261 are meant for housing the active elements. Top and bottom high stiffness plates 269 of only half the number of similarly shaped holes are rigidly screwed and/or bonded onto the connector 261 to form the modified connector 260 as shown. Section E-E shown all six connector recesses 265, and Section F-F show the placement of the high stiffness plates 269 onto the connector 261.

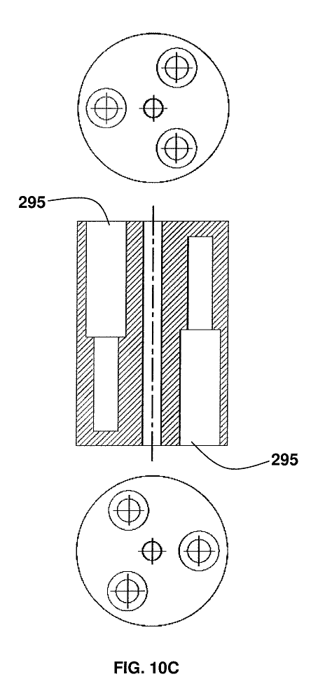

To aid in the handling of the disclosed actuators during fabrication, side openings 291, side openings 293 and base openings 295 of various forms and dimensions may be incorporated in non-critical part of the connector. Examples of such are shown in FIGS. 10A, 10B and 10C. Care should be exercised to ensure that such openings produce no adverse effect to the stiffness of the connector, namely, they should not lead to significant increase in the deflection of the connector during use.

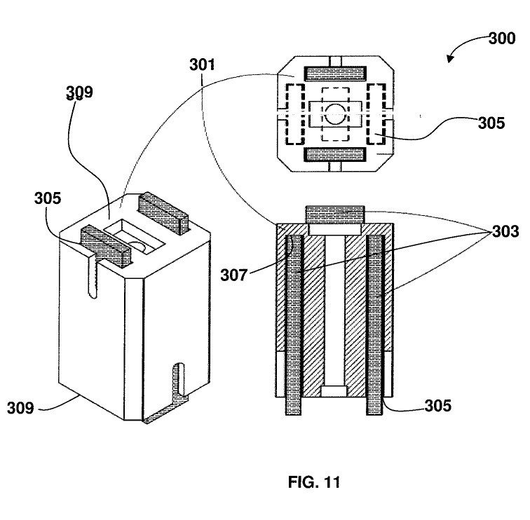

FIG. 11 shows top, sectional, and isometric views of an example of an HBS-2×-assemblage 300 comprising a HBS-2×-connector 301 of square overall cross-section, in accordance with the present invention. To form the HBS-2×-assemblage 300, four appropriately wired active elements 303 of suitable length, that is, slightly longer than the depth of the connector recesses 305 are bonded with an suitable agent, such as epoxy, for example, onto bases 307 of respective connector recesses 305 of the HBS-2×-connector 301, with the opposite end faces of the upper set of active elements 303 protruding from the top base 309 and the lower set of active elements 303 protruding from the bottom base 309 of the HBS-2×-connector 301 as shown. Suitable slot openings and/or wire feed-through holes may be incorporated in the design for ease of device fabrication as shown but they should not adversely affect the bending stiffness of the connector. Preferably, the total cross-sectional areas of the active elements per level are about the same so that the blocking forces produced by respective levels are approximately the same although this is not a must.

Finite element analysis on the connector configurations disclosed herein has shown that even with an aluminum connector, the bending displacement of the base of the connector produced by an axial load via the active elements is greatly reduced over the conventional designs (described above), being at most few percentage of the overall displacement. It should be noted that the bending displacement of the connector acts against the desired displacement of the resultant actuator under load and hence is undesirable. Even smaller bending displacement is expected should the connector be made of materials of higher elastic modulus including but not limited to a light metal, an engineering ceramic, an iron-alloy, a nickel-alloy, a copper-based alloy, a fibre-reinforced polymer or tungsten carbide-cobalt (WC—Co) cermets.

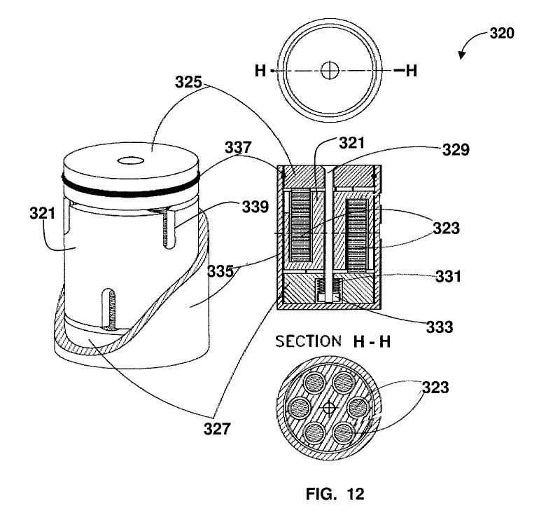

FIG. 12 shows top, bottom, sectional, and perspective views of an example of a two-level (2×) actuator 320 made from an HBS-2×-assemblage 321 of the present invention, in which active elements 323 are made of piezoelectric ceramic stacks of a circular cross-section. To form the two-level actuator 320, the exposed end faces of the top and bottom sets of active elements 323 of the HBS-2×-assemblage 321 are bonded with a suitable agent onto a rigid pedestal 325 and a base plate 327 of the actuator 320 respectively, as shown. A stress rod 329 with coil springs 331 and lock nuts 333 are incorporated to place the active elements 323 and the various epoxy joints in compression, which is optional. The HBS-2×-assemblage 321 is inserted into a casing 335 as shown. One or more O-rings 337 or other highly compliant materials may be used in between the pedestal 325 and the casing 335 to enable the pedestal 325 to move freely during activation. Optional slot openings 339 may be provided for ease of wire connection during device fabrication. Other designs of the pedestal 325, the base plate 327, pre-stress mechanism and the casing 335 are possible to suit various applications. The lead wires connecting the active elements 323 are not shown in this figure for clarity of illustration.

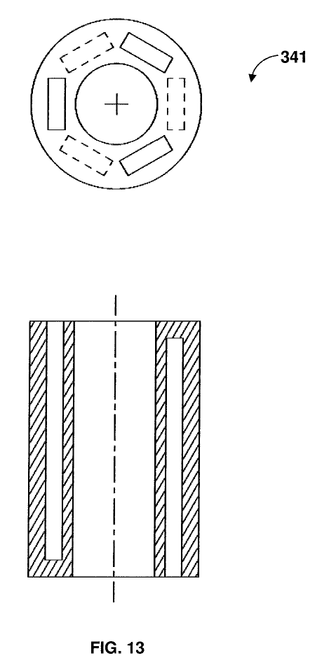

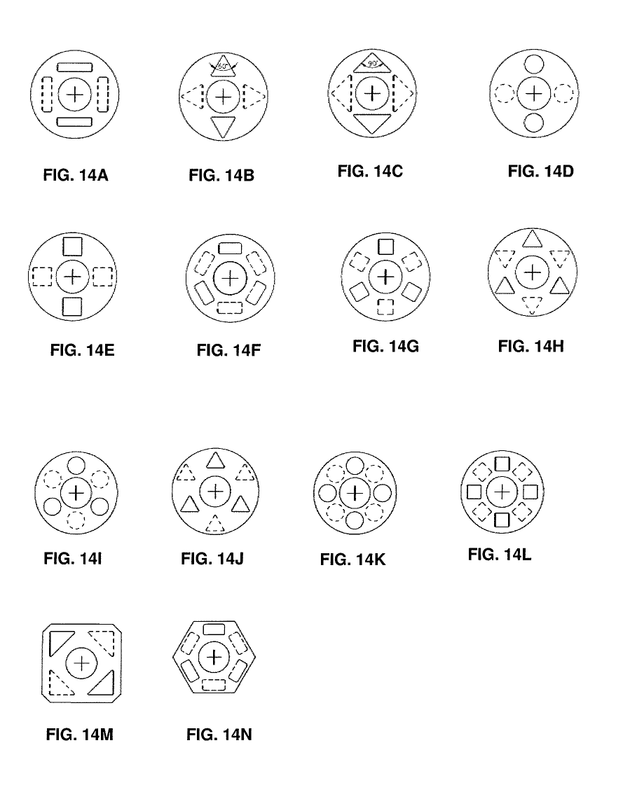

In contrast, FIG. 13 and FIG. 14A to FIG. 14N show a ring HBS-2×-connector 341 of the present invention, but having ring cross-section and, alternatively, may have a polygonal pseudo-ring cross-section. Compared with the designs shown in FIGS. 6 to 12, the ring HBS-2×-connector 341 has a much larger inner bore to suit a desired application. As a result, actuators made of such HBS-2×-connectors and assemblages have larger footprints.

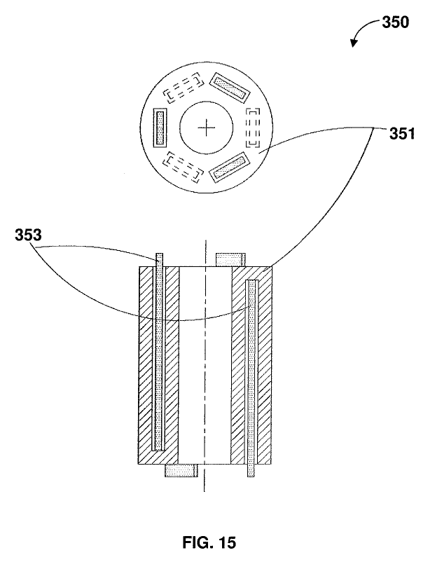

FIG. 15 shows another example of an HBS-2×-assemblage 350 of the present invention. The HBS-2×-assemblage 350 comprises a ring-shaped HBS-2×-connector 351 and two sets of three rectangular active elements 353 each. The top set of three active elements 353 protrudes from the top face of the connector 351, while the bottom set protrudes from the bottom face. When a suitable voltage is applied to the active elements 353, the top set of active elements 353 will extend or contract in the top-pointing direction, while the bottom set of active elements 353 will extend or contract in the bottom-pointing direction, thus enabling the HBS-2×-assemblage 350 to function as a displacement actuator in both directions.

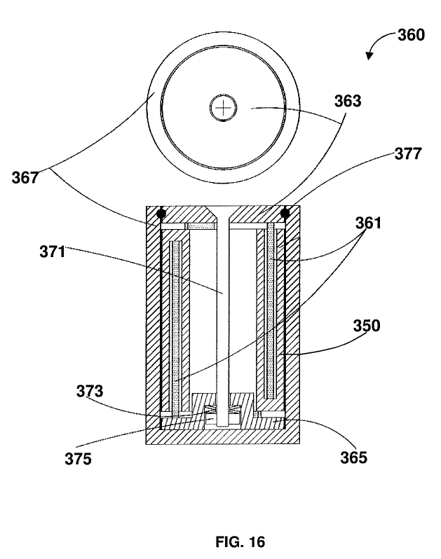

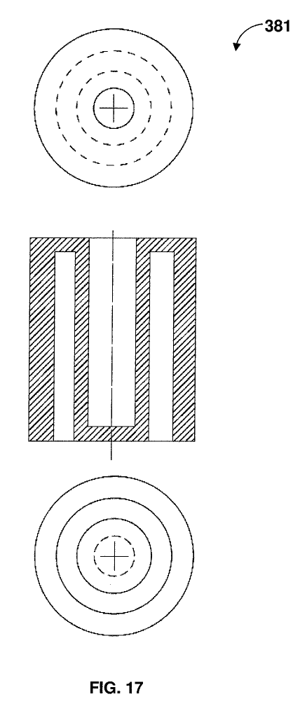

FIG. 16 shows top and sectional views of an example of a two-level (2×) actuator 360 that includes the HBS-2×-assemblage 350, shown in FIG. 15. The active elements 361 in this configuration are transverse-mode piezoelectric single crystals or piezo-ceramic bars of rectangular shape. To form the two level actuator 360, the end faces of the top set of active elements 361 of the HBS-2×-assemblage 350 are bonded with a suitable agent onto the base of a top rigid pedestal 363, while the bottom set of active elements 361 are bonded to the top face of a base plate 365, as shown. A stress rod 371 with disc springs 373 and lock nuts 375 are optional in the design of the two-level (2×) actuator 360. The lead wires connecting the active elements are not shown in this figure for clarity of illustration. The assembly in FIG. 16 may be used as the finished actuator or may be inserted into a protective casing 367, as shown in the figure. In this example, an O-ring 377 is used to ensure free movement of the pedestal 363 during actuation.

Yet another example of an HBS-2×-connector 381 of the present invention is that of concentric ring designs but with a thick and rigid outer shell as shown via top, sectional, and bottom views in FIG. 17. The thick outer shell is a key design feature of the present invention. Its thickness, together with the thickness of the bases of the connector recesses, should be such that the bending displacement of the base of the connector recesses in the axial direction of the HBS-2× connector 381 is not more than 20% of the overall displacement of individual active elements.

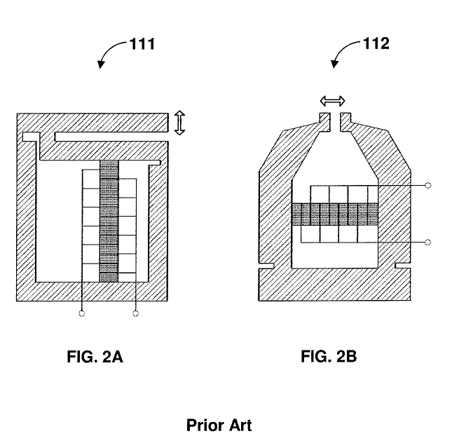

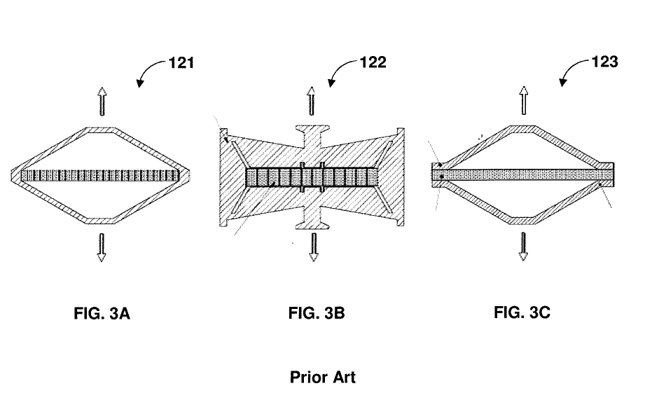

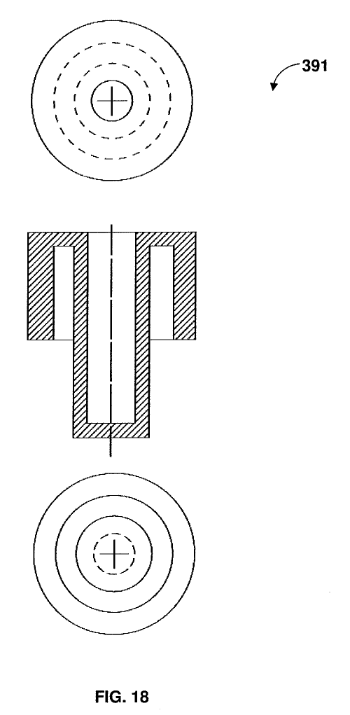

FIG. 18 shows top, sectional, and bottom views of a modified design of a concentric ring HBS-2×-connector 391 with a shorter outer shell for ease of device fabrication. It is important in such a design that, the shorter outer shell is thick and rigid to limit the bending displacement of HBS-2×-connector 391 to not more than 20% of the overall displacement of individual active elements. Concentric ring designs, as illustrated in FIGS. 17 and 18, are simple and cost effective to produce but they may not be as rigid as the designs shown in FIGS. 2 to 16. It should be noted that the thickness of the outer shell in the ring HBS-2×-connector 381 shown in FIG. 17 and the thickness of the outer shell in the ring HBS-2×-connector 391 shown in FIG. 18, each ranges from 0.2 to 0.5 times the width of the respective connector recesses of ring shape.

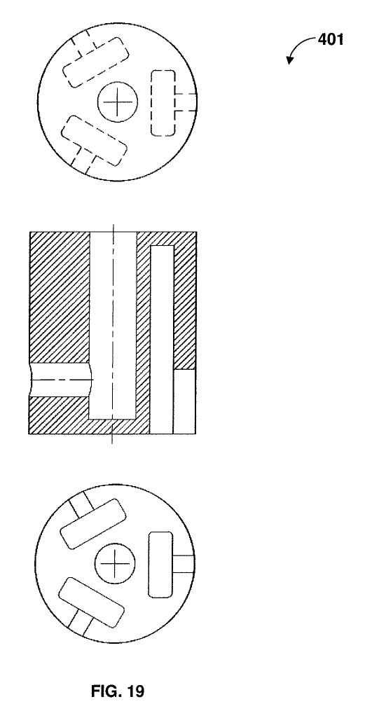

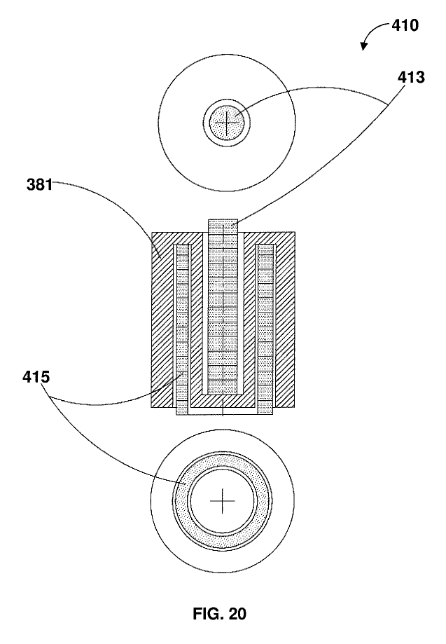

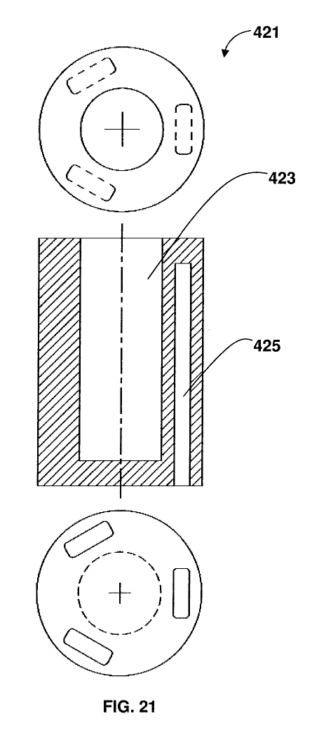

A design similar to the HBS-2×-connector 391 of FIG. 18, but of improved bending stiffness, is shown in top, sectional, and bottom views of FIG. 19. In this design of an HBS-2×-connector 401, there is no outer ring-like recess, but has a suitable number of segmented recesses of a circular cross-sectional shape, a triangular cross-sectional shape, a square cross-sectional shape, a rectangular cross-sectional shape, a ring shape, a polygonal cross-sectional shape, a V-channel cross-sectional shape, a T-channel cross-sectional shape, or an L-channel cross-sectional shape for housing individual active elements of similar cross-sections. The slot openings and through holes on the outer shell are for ease of device fabrication and handling, of which the dimensions and locations should be carefully selected such that they would not adversely affect the bending stiffness of the connector.

Alternatively, the segmented recesses in the outer shell of the HBS-2×-connector 401 in FIG. 19 may be of curved or arch-shaped cross-section (not shown) to house active elements which are produced by slicing a d₃₁-mode piezo-ceramic tube length-wise into several equal pieces. Active elements made of such, however, may have reduced overall displacement due to the lower d₃₁ piezoelectric strain coefficient of present-day piezo-ceramics.

FIG. 20 shows an example of an HBS-2×-assemblage 410 that includes the HBS-2×-connector 381 shown in FIG. 17, a d₃₃ stack of either square or circular cross-section of active elements 413 in the middle connector recess of the HBS-2×-connector 381, and a d₃₃-ring stack 415 in an annular connector recess of the HBS-2×-connector 381. The lead wires connecting the active elements 413 and stack 415 are not shown in this figure for clarity of illustration. The HBS-2×-assemblage 410 may be used as the finished actuator. Alternatively, a protective casing (not shown) may be used in the design.

Since HBS-2×-connectors of the present invention are rigid with high bending stiffness, the displacement produced by the two-level (2×) actuator made from HBS-2×-connectors, as exemplified by FIGS. 12, 16 and 20, will be approximately the sum of displacement exhibited by individual levels. In other words, if all active elements are of the same cut and dimensions, then the displacement produced by the two level (2×) actuator of the present invention will be approximately twice that of individual active elements, while the blocking force of the two level actuator is about n-times larger, where n is the number of active elements per level.

It should be noted that the blocking force of the resultant actuator could be increased either by: (i) using active elements of larger cross-sectional (i.e., load bearing) area, or (ii) using a larger number of active elements per level, without significantly increasing the foot-print of the actuator.

Alternatively, the blocking force of the resultant actuator may be doubled or tripled by connecting two or three units of HBS-2×-assemblages in parallel in forming the resultant actuator.

Solid and hollow triangular cross-sectioned active elements

It can be seen from FIGS. 5 to 20 that for a given connector cross-sectional area, H BS-assemblages with closely spaced active elements of triangular cross-sections, as in FIGS. 6E, 6J, 6S and 6W, offer a larger total load-bearing area and hence blocking force, bending and twisting strengths of the resultant device. Thus, active elements of solid triangular or triangular-pipe cross-section of either longitudinal (d₃₃) mode or transverse (d₃₁ or d₃₂) mode are also possible with the HBS-connector.

It is imperative that active elements of solid or hollow triangular cross-section (i) having chamfered or rounded corners, or (ii) having their acute corners protected or strengthened with adequate means, be used in making the HBS-assemblages and actuators of the present invention.

3×-HBS Connectors, Assemblages and Actuators

FIG. 21 shows top, sectional, and bottom views of an exemplary HBS-3×-connector 421 of the present invention. The HBS-3×-connector 421 includes a bore 423 of sufficiently large diameter so as to accommodate a cylindrical 2×-HBS-assemblage, that includes a HBS-2×-connector (not shown) with top and bottom sets of active elements (not shown). The HBS-3×-connector 421 includes connector recesses 425 suitable for housing an additional set of active elements (not shown) of the desired cross-section, which are rectangular in the example shown. The thick recess-containing outer shell provides the needed stiffening effect and is a key feature of the exemplary embodiment shown.

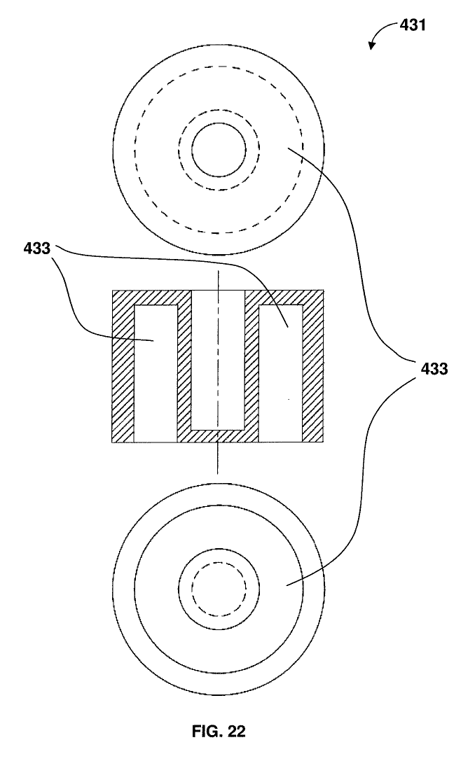

FIG. 22 shows top, sectional, and bottom views of yet another example of an HBS-3×-connector 431 of the present invention. The HBS-3×-connector 431 is of similar design to the HBS-2×-connector 381 of FIG. 17 except that an outer ring recess 433 is of sufficient width to house a ring HBS-2×-assemblage instead. The thick outer shell of the HBS-3×-connector 431 provides the needed stiffening effect and is a key feature of the present invention. Instead of circular overall cross-section, the HBS-3×-connectors 421 and 431 of the present invention can be of any overall cross-section including a square, a circular, a rectangular, a ring, and other polygonal shapes to suit various applications.

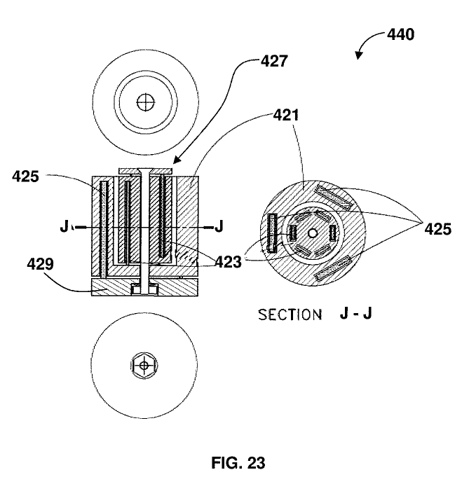

FIG. 23 shows top, sectional, and bottom views of an example of a three level (3×) actuator 440 with a stress rod using the HBS-3×-connector 421 of FIG. 21. To make the three-level actuator 440, the cylindrical HBS-2×-assemblage 350, shown in FIG. 15, is carefully positioned inside the central recess of the HBS-3×-connector 421, and the end faces of the bottom set of active elements 423 are bonded onto the base of the central connector recess in the HBS-3×-connector 421. Then, an additional set of active elements 425 are bonded onto the bases of an outer, annular connector recess in the thick outer shell of the HBS-3×-connector 421.

The top-most and bottom-most free end faces of the active elements 423 of the resultant 3×-assemblage 440 are then bonded onto a rigid pedestal 427 and the base plate 429 of the three level (3×) actuator 440, respectively. The stress rod may then be inserted, and all the active elements 423, 425 and the adhesive joints are loaded with predetermined compression via disc springs and lock nuts. The three level (3×) actuator 440 may also be housed inside a suitable casing (not shown) for improved protection. Also not shown for clarity of illustration are the lead wires connecting to the active elements 423, 425. Other designs of the pedestal, base plate, pre-stress mechanism and casing of the three level (3×) actuator 440 are possible to suit various applications.

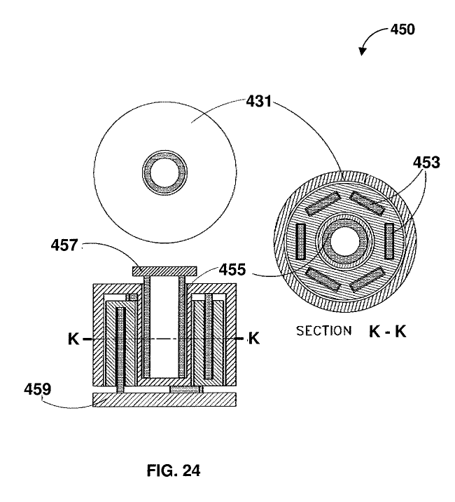

FIG. 24 shows top and sectional views of yet another example of a three-level (3×) actuator 450 made using the HBS-3×-connector 431 shown in FIG. 22. To construct the three-level actuator 450, the ring HBS-2×-assemblage may be appropriately positioned inside the outer ring recess of the HBS-3×-connector 431, and the end faces of the bottom set of active elements 453 are bonded onto the bases of ring the connector recesses of the HBS-3×-connector 431. Then a d₃₃ stack or a d₃₁ tube active element 455 of desired deformation characteristics, or a number of active elements of a selected configuration, is/are bonded onto the base of the central recess. The top-most and bottom-most free end faces of the active elements 455 and of the resultant 3×-HBS assemblage 350 of FIG. 15 are then bonded onto a rigid pedestal 457 and a base plate 459 of the actuator, respectively. As in the previous example, the above assembly may be used as an actuator or it may be placed inside a suitable casing, (not shown). Also not shown, for clarity of illustration are the lead wires, lead wire through-holes, and openings for ease of fabrication. Other designs of the pedestal, base plate, pre-stress mechanism and casing of the actuator are possible to suit various applications.

The three level actuator 440, 450 designs shown in FIG. 23 and FIG. 24 are sufficient when the desired blocking forces are low to moderate.

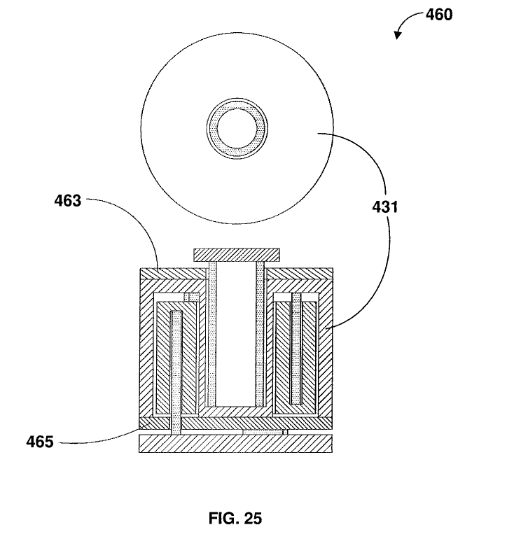

When larger blocking forces are required, the bending stiffness of the HBS-3×-connectors may be further enhanced by incorporating additional stiffening disks or plates 463 and 465 onto the top and/or bottom faces of the connector 431 to make the three-level actuator 460, as shown in FIG. 25. The top and bottom stiffening disks 463, 465 or plates should have appropriate windows for the top-most and bottom-most sets of protruding active elements to enable them to function as intended.

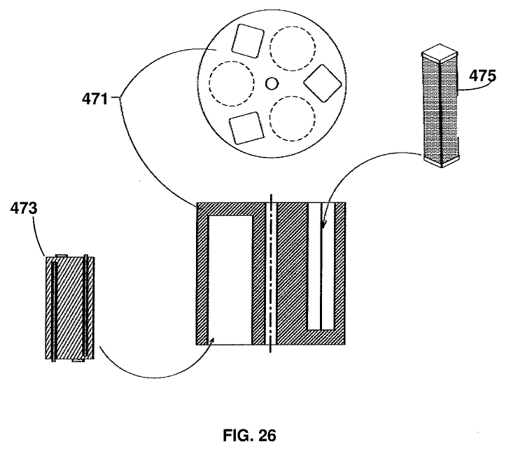

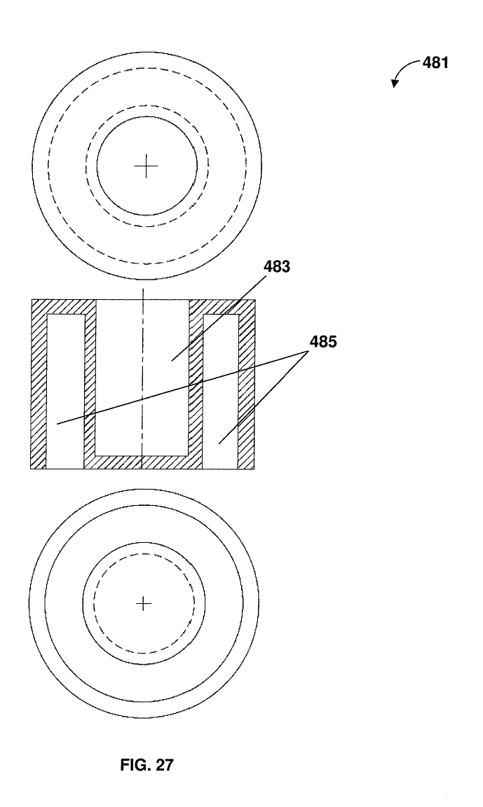

FIG. 26 shows yet another example of an HBS-3×-connector 471 of the present invention. In this example, all the active elements are circumferentially deposited. The large recess housings are for cylindrical 2×-HBS-assemblages 473 while the smaller ones are for the third set of active elements 475 which are of square cross-section in the figure shown. Active materials of other cross-sections can also be used to suit a particular application.

4×-HBS Connectors, Assemblages and Actuators

FIG. 27 shows an example design of a HBS-4×-connector 481 for making four-level (4×) actuators of low-to-moderate blocking forces. In this design, a central recess 483 is used to house a 2×-cylindrical-HBS-assemblage and an outer ring recess 485 is used to house a 2×-ring-HBS-assemblage. The thick outer shell and connector recess base provide the needed stiffening effect and are key features of the present invention.

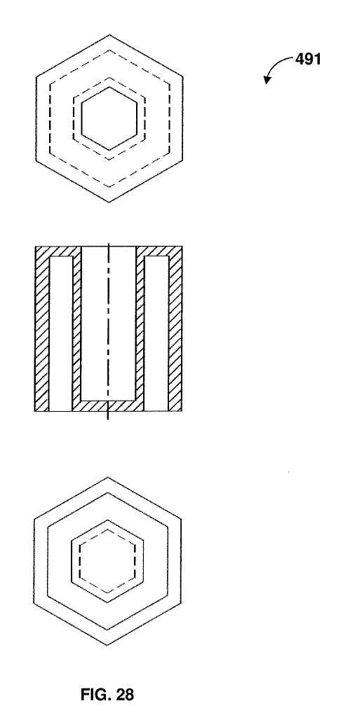

Instead of having circular overall cross-sections, the 2×-, 3×- and 4-x-HBS-connectors of the present invention can be of any suitable overall cross-section to suit various applications. As an illustration, FIG. 28 shows a polygonal design of the HBS-4×-connector 491 which is suitable for making four level (4×) actuators of polygonal cross-section. Again, the thick outer shell and connector recess base provide the needed stiffening effect and are key features of the present invention.

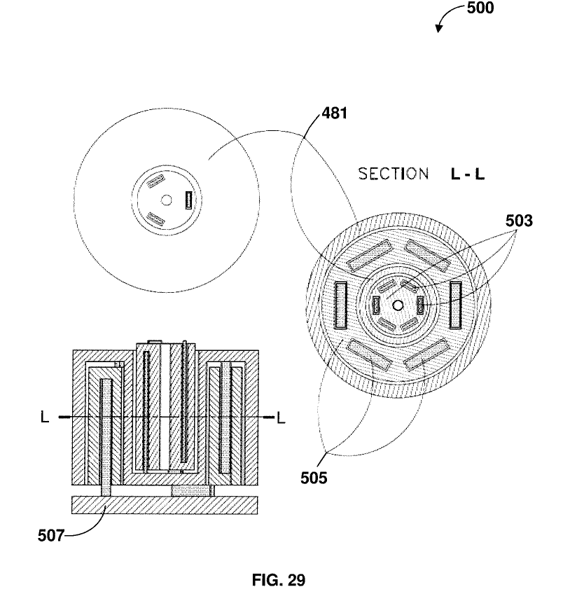

FIG. 29 shows an example of a four-level (4×) actuator 500 made from a HBS-4-connector 481 of FIG. 27. To make the four-level (4×) actuator 500 using the HBS-4-connector 481, a cylindrical HBS-2×-assemblage 503 is placed inside and bonded onto the base of the central connector recess of the HBS-4-connector 481, while a ring HBS-2×-assemblage 505 is placed inside and bonded onto the base of the outer ring recess. The rigid pedestal (not shown) and the base plate 507 are then bonded onto the exposed top-most active element end faces of the assemblage 503 and the exposed bottom-most active element end faces of the assemblage 505, respectively. The assembly may be used as an actuator or placed inside a suitable casing (not shown in this figure; also not shown are the lead wires and wire feed-through holes and openings for clarity of illustration) for improved protection. Other designs of the pedestal, the base plate, optional pre-stress mechanism and the casing of similar 4×-actuators are possible to suit various applications.

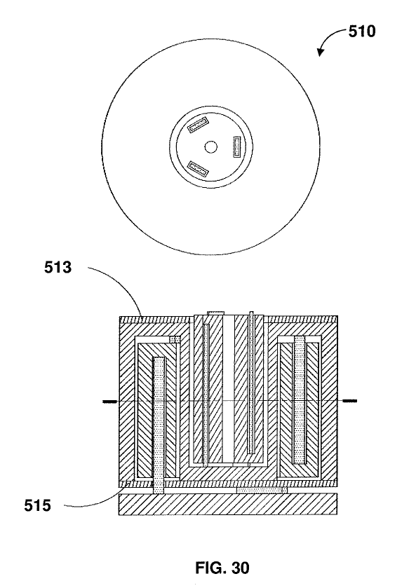

FIG. 30 shows an example design of HBS-4×-actuator or four-level actuator 510 for high blocking force applications. In this example, additional top and bottom stiffening plates 513 and 515 are firmly attached to the top and bottom faces of the HBS-4×-connector 481 of FIG. 29. The top and/or bottom stiffening plates or disks have appropriate openings to enable the top-most and bottom-most sets of active elements to protrude and to function as intended.

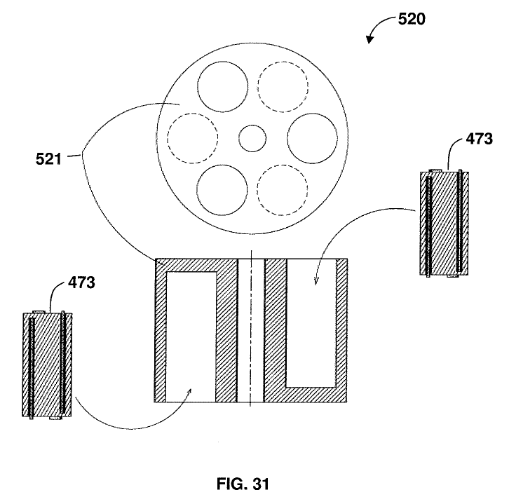

FIG. 31 shows another example design of an HBS-4×-connector 521 and a four level actuator 520 made from the HBS-4×-connector 521, in which alternating top- and bottom-directed cylindrical HBS-2×-assemblages 473 are positioned circumferentially. Such a design has a larger foot-print as opposed to those described previously but may find application when actuators of higher bending and/or twisting strength are required.

Preferably, the HBS-2×-, HBS-3×- and HBS-4×-connectors of the present invention are made of ductile and high modulus materials including but not limited to light metals, engineering ceramics and fibre-reinforced polymers.

Light metals of high elastic modulus which can be processed after machining or forming to give it an insulation surface layer will be advantageous. Anodized aluminum and suitable aluminum alloys are such materials which are highly suitable for making the HBS connectors of the present invention.

Alternatively the connectors may be made of a high-modulus and high-strength engineering materials including suitable iron-, nickel- and copper-based alloys and WC—Co cermets. In using these materials, the connector should be electrically insulated from the electrical contacts of the active elements.

Derivative Devices

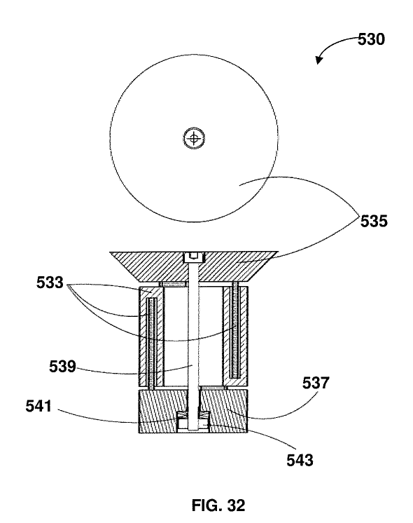

FIG. 32 shows an example derivative device 530 made from a HBS-connector of the present invention. It shows a Langevin (or Tonpilz) underwater projector in which a HBS-2×-assemblage 533 similar to that shown in FIG. 15 is used as its motor section together with a head mass 535, tail mass 537, stress rod 539, disc springs 541 and lock nuts 543. For a given design frequency, the use of an HBS-connector and assemblage shortens the overall height of the projector, thus making possible compact low-frequency (<15 kHz) Langevin underwater projectors. In this example, the HBS-connector acts as an intermediate mass which, when appropriately designed, also helps to increase the bandwidth of such devices.

For lower operating frequencies, Langevin underwater projectors using 3×- or 4×-HBS-assemblage as their motor section would be more appropriate. The use of HBS-connectors and assemblages thus make possible a wide range of compact low-frequency underwater projectors suitable for underwater ranging, communicators and imaging application.

It will be obvious to a skilled person that the configurations, dimensions, materials of choice of the present invention may be adapted, modified, refined or replaced with slightly different but equivalent designs without departing from the principal features of the working principle of our invention, and additional features may be added to enhance the bending stiffness of the connectors-cum-displacement-multipliers. For instance, the present concept can be extended readily to make HBS-5× and HBS-6× connector and associated five level and six level actuators via appropriate but simple design modifications. Furthermore, additional protection features, as use of corrosion resistant materials and the incorporation of anti-twisting features may be incorporated in the design of the final devices. These substitutes, alternatives, modifications, or refinements are considered as falling within the scope and letter of the following claims.

Moreover, any of the above disclosed active elements can be fabricated from individual and/or bonded assemblages of piezoelectric single crystal , as is known in the relevant art. For example, a component piezoelectric crystal can be a rectangular crystal bar, a crystal rod, or a crystal tube of either longitudinal (d₃₃) or transverse “(d₃₁ or d₃₂) mode. The bonded active elements can be a longitudinal or transverse-mode active element of solid or hollow cross-section, including triangular or triangular-pipe cross section, square or square-pipe cross section, or of any other polygonal-pipe cross-section.

Although embodiments of the current disclosure have been described comprehensively, in considerable detail to cover the possible aspects, those skilled in the art would recognize that other versions of the disclosure are also possible. Furthermore, variations of the above disclosed and other features and functions, or alternatives thereof, may be desirably combined into many other different systems or applications. These alternatives, modifications, variations or improvements, which may be subsequently made by those skilled in the art for various applications, are also considered to be encompassed by the following claims.

1.-33. (canceled)

34. A small footprint high bending stiffness connector for use with a plurality of piezoelectric active elements to form a multi-level axial displacement piezoelectric actuator of large overall axial displacement and blocking force, said connector comprising:
a substantially solid cylindrical component having a first base, and a second base in an opposed, substantially parallel relationship to said first base;
a set of multiple connector recesses equally spaced and arranged circumferentially extending substantially through the connector from said first base, perpendicular to said first base; and
a set of multiple connector recesses equally spaced and arranged circumferentially extending substantially through the connector from said second base, perpendicular to said second base, which intersperse with the set of recess housings extending from the first base at approximately equal angular separation along the circumference of the connector;
wherein each connector recess can house a piezoelectric active element;
wherein the cross-section of each connector recess is substantially equal to that of the piezoelectric active element that it houses;
wherein the base of each connector recess is firmly connected to the connector body to avoid cantilever loading during use;
wherein the depth of each connector recess is preferably slightly shorter than the length of the piezoelectric active element that it houses; and
wherein the piezoelectric active elements housed in both sets of connector recesses operate in unison to produce an overall axial displacement approximately twice (2×) that of respective piezoelectric active elements and of blocking force comparable to or larger than that of respective piezoelectric active elements.

35. The connector as claimed in claim 34, wherein the cross-section of said connector comprises one of a circular shape, a square shape, a rectangular shape, a polygonal shape, a ring shape, or a polygonal ring shape, wherein the cross-sectional shape of said connector recess is approximately the same as the cross-sectional shape of a housed piezoelectric active element and is at least one of a circular shape, a square shape, a rectangular shape, a triangular shape, a V-channel shape, a T-channel shape, or an L-channel shape.

36. The connector of claim 34, wherein said bases are unitary with said connector.

37. The connector of claim 34, wherein said bases are mechanically fastened and/or bonded to said cylindrical component.

38. The connector of claim 34, wherein at least one of said connector recesses for housing said piezoelectric active elements comprises a ring shape, preferably, said ring shape connector recesses comprises an outer shell having a thickness in the range of 0.2 to 0.5 times the width of said connector recesses of said ring shape.

39. The connector of claim 34, wherein said connector comprises at least one opening to aid handling during manufacture of actuators from said connector.

40. The connector of claim 34, further comprising at least one high-stiffness load pad bonded to a base inside at least one of said connector recess.

41. The connector of claim 34, further comprising at least one stiffening plate bonded onto one or both end faces of said connector.

42. The connector of claim 34, further comprising a central connector hole passing through said connector.

43. The connector of claim 34, wherein said connector is made of one of a high modulus material, a light metal, an engineering ceramic, or a fibre-reinforced polymer.

44. An assemblage comprising at least one connector of claim 34, at least one upper piezoelectric active element and at least one lower piezoelectric active element wherein said at least one upper piezoelectric active element protrudes from said first base and said at least one lower piezoelectric active element protrudes from said second base.

45. The assemblage of claim 44, wherein said upper and lower piezoelectric active elements comprise a cross sectional shape of a solid triangle, a hollow triangle, a solid square, a hollow square, a solid rectangle, a hollow rectangle, a solid cylinder, a hollow cylinder, a ring, a pseudo-ring of a polygonal form, a V-channel shape, a T-channel shape, or a L-channel shape, of either longitudinal (d₃₃) or transverse (d₃₁ or d₃₂) activation mode.

46. The assemblage of claim 44, wherein each of said upper and lower piezoelectric active elements is made of an individual piece or a bonded structure of piezoceramic or piezoelectric single crystal.

47. The assemblage of claim 44, wherein said piezoelectric active elements comprise at least one of a lead zirconate titanate piezoceramic or a compositionally-modified derivative of lead zirconate titanate piezoceramic, or a single crystal selected from the group consisting of lead zinc niobate-lead titanate [Pb(Zn_{1/3}Nb_{2/3})O₃-PbTiO₃], lead magnesium niobate-lead titanate [Pb(Mg_{1/3}Nb_{2/3})O₃—PbTiO₃], lead magnesium niobate-lead zirconate-lead titanate [Pb(Mg_{1/3}Nb_{2/3})O₃—PbZrO₃—PbTiO₃], and lead indium niobate-lead magnesium niobite-lead titanate [Pb(In_{1/2}Nb_{1/2})O₃—Pb(Mg_{1/3}Nb_{2/3})O₃—PbTiO₃] including their compositionally modified derivatives.

48. An actuator comprising at least one said assemblage of claim 44, wherein the upper piezoelectric elements and the lower piezoelectric elements work in unison and contribute to the overall axial displacement of the actuator.

49. The actuator of claim 48, further comprising at least one pedestal, a base plate, a pre-stress mechanism, and a casing.

50. The actuator of claim 48, further comprising an anti-twist mechanism.

51. An underwater projector comprising a motor section having at least one of said connector of claim 34 and an assemblage, wherein the assemblage comprises the connector, at least one upper piezoelectric active element and at least one lower piezoelectric active element wherein said at least one upper piezoelectric active element protrudes from said first base and said at least one lower piezoelectric active element protrudes from said second base.

52. The underwater projector of claim 51, further comprising at least one of a head mass, a tail mass, a pre-stress mechanism, and a casing.
